(19) United States
(12) Patent Application Publication
(10) Pub. No.: US 2006/0214233 A1
(43) Pub. Date: Sep. 28, 2006

(54) FinFET semiconductor device

(76) Inventors: Hari P. Ananthanarayanan, West Lafayette, IN (US); Aditya Bansal, West Lafayette, IN (US); Kaushik Roy, West Lafayette, IN (US)

Correspondence Address: BARNES & THORNBURG, 11 SOUTH MERIDIAN, INDIANAPOLIS, IN, 46204, US

(21) Appl. No.: 11/086,608

(22) Filed: Mar. 22, 2005

(51) Int. Cl. H01L 27/12

(52) U.S. Cl. 257/353

(57) ABSTRACT

A FinFET semiconductor device includes a source region, a drain region, and a channel region defined therebetween. The source region, drain region, and channel region form a fin structure extending upwardly away from a substrate to a fin height greater than a standard minimum fin height.

### BACKGROUND

The present disclosure relates generally to semiconductor devices, and more particularly, to Field-Effect-Transistors.

Fin-type Field-Effect-Transistor devices (FinFETs) are typically constructed with the source, drain and channel regions forming a fin structure that extends upwardly away from the substrate upon which they are formed. Current flows laterally through the channel region of the fin structure between the drain and source regions.

### SUMMARY

The present invention comprises one or more of the features recited in the appended claims and/or the following features which, alone or in any combination, may comprise patentable subject matter:

A FinFET semiconductor device is provided. The FinFET semiconductor device may be fabricated according to a predetermined technology node process (e.g., the 65 nm technology node). The predetermined technology node process may define a minimum fin height. The FinFET device may be fabricated on a substrate. The substrate may be a silicon substrate. The FinFET device may include a source region, drain region, and a channel region defined between the source and drain regions. The source, drain, and channel regions may form a fin structure. The fin structure may extend upwardly away from the substrate to a fin height greater than the minimum fin height. For example, the fin height may be more than fifty percent greater than the minimum fin height. In particular, the fin height may be about sixty-nine percent greater than the minimum fin height. The technology node process may further define a minimum fin pitch value and a maximum fin aspect ratio value. In some applications, the fin height may be any value in between a minimum value defined as half of the minimum pitch value and up to and including a maximum value defined as the product of the maximum fin aspect ratio value and the body thickness of the fin structure. The FinFET device may also include one or more gate regions adjacent to the channel region on one or more sides of the fin structure. Further, the technology node process may define a minimum voltage threshold value. The FinFET device may have a voltage threshold which is greater than the minimum voltage threshold. In some embodiments, the FinFET device may include additional fin structures, each having a source, drain, and channel regions. In such embodiments, the fin height of each fin structure is greater than the minimum fin height. In one particular embodiment, the FinFET device forms a portion of an SRAM device.

An electrical circuit is also provided. The electrical circuit may include a FinFET semiconductor device fabricated on a substrate. The FinFET device may be fabricated according to a predetermined technology node process (e.g., the 65 nm technology node). The predetermined technology node process may define a minimum fin height and a minimum supply voltage. The FinFET device may include a source region, a drain region and a gate region defined therebetween. The source region, drain region, and gate regions may form a fin structure. The fin structure may extend upwardly away from the substrate to a fin height greater than the minimum fin height. For example, the fin height may be more than fifty percent greater than the minimum fin height. In particular, the fin height may be about sixty-nine percent greater than the minimum fin height. The fin height may allow for a supply voltage applied to the FinFET device that is less than the minimum supply voltage. For example, the supply voltage may be about ten percent lower than the minimum supply voltage. In one particular embodiment, the supply voltage is about eighteen percent lower than the minimum supply voltage. The technology node process may further define a minimum fin pitch value and a maximum fin aspect ratio value. In some applications, the fin height may be any value in between a minimum value defined as half of the minimum pitch value and up to and including a maximum value defined as the product of the maximum fin aspect ratio value and the body thickness of the fin structure. The FinFET device may also include one or more gate regions adjacent to the channel region on one or more sides of the fin structure. Further, the technology node process may define a minimum gate workfunction. The minimum fate workfunction may define a minimum voltage threshold. The voltage threshold of the FinFET device may be lower than the minimum voltage threshold. In some embodiments, the FinFET device may include additional fin structures, each having a source, drain, and channel regions. In such embodiments, the fin height of each fin structure is greater than the minimum fin height. In one particular embodiment, the FinFET device forms a portion of an SRAM device.

A method of fabricating a FinFET semiconductor device on a substrate is also provided. The FinFET device may be fabricated according to a predetermined technology node process. The predetermined technology node process may define a minimum fin height. The method may include forming on the substrate a fin structure having a source region, a drain region, and a channel region therebetween. The method may also include forming a gate region adjacent to the channel region on at least one side of the fin structure. The fin structure may extend upwardly away from the substrate to a fin height greater than the minimum fin height. The fin height may be more than fifty percent greater than the minimum fin height. In particular, the fin height may be about sixty-nine percent greater than the minimum fin height. The technology node process may further define a minimum fin pitch value and a maximum fin aspect ratio value. In some applications, the fin height may be any value in between a minimum value defined as half of the minimum pitch value and up to and including a maximum value defined as the product of the maximum fin aspect ratio value and the body thickness of the fin structure. Additionally, the method may include forming a single electrically conductive gate over the gate region.

In addition, an SRAM device is provided. The SRAM device may be fabricated according to a predetermined technology node process and may include at least one FinFET device. The technology node process may define a minimum fin height for the FinFET. The FinFET device may have a source region, a drain region, and a channel region defined therebetween. The source region, drain region, and channel region may define a fin structure. The fin structure may extend upwardly away from the substrate to a fin height greater than the minimum fin height.

The above and other features of the present disclosure, which alone or in any combination may comprise patentable subject matter, will become apparent from the following description and the attached drawings.

### BRIEF DESCRIPTION OF THE DRAWINGS

The detailed description particularly refers to the following figures, in which:

FIG. 1a is a perspective view of a FinFET device having a fin height greater than a minimum fin height;

FIG. 1b is a cross-sectional view of the FinFET device of FIG. 1a taken generally along section line 1b-1b;

FIG. 2 is a perspective view of the FinFET device in FIG. 1 having multiple fins; and

FIG. 3 is a simplified schematic of a six transistor SRAM cell including a number of the FinFET devices of FIG. 1 and/or FIG. 2.

### DESCRIPTION OF THE ILLUSTRATIVE EMBODIMENTS

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives falling within the spirit and scope of the disclosure.

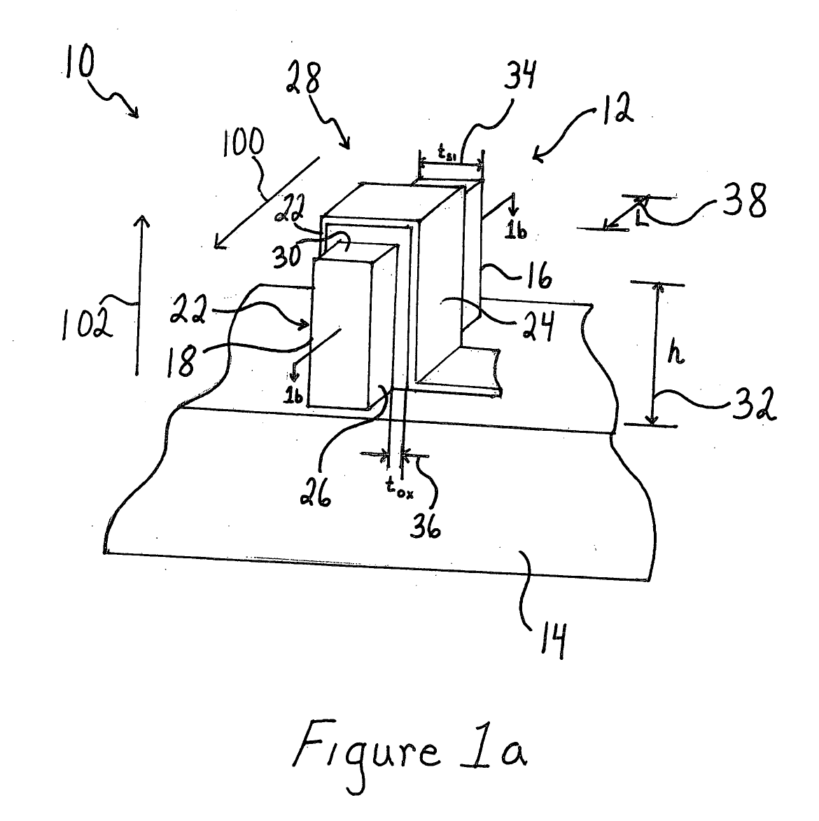

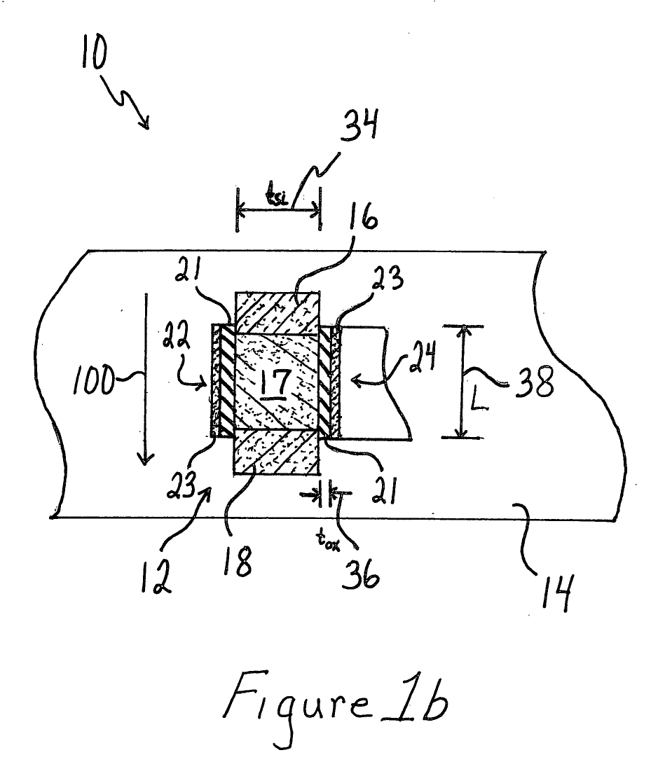

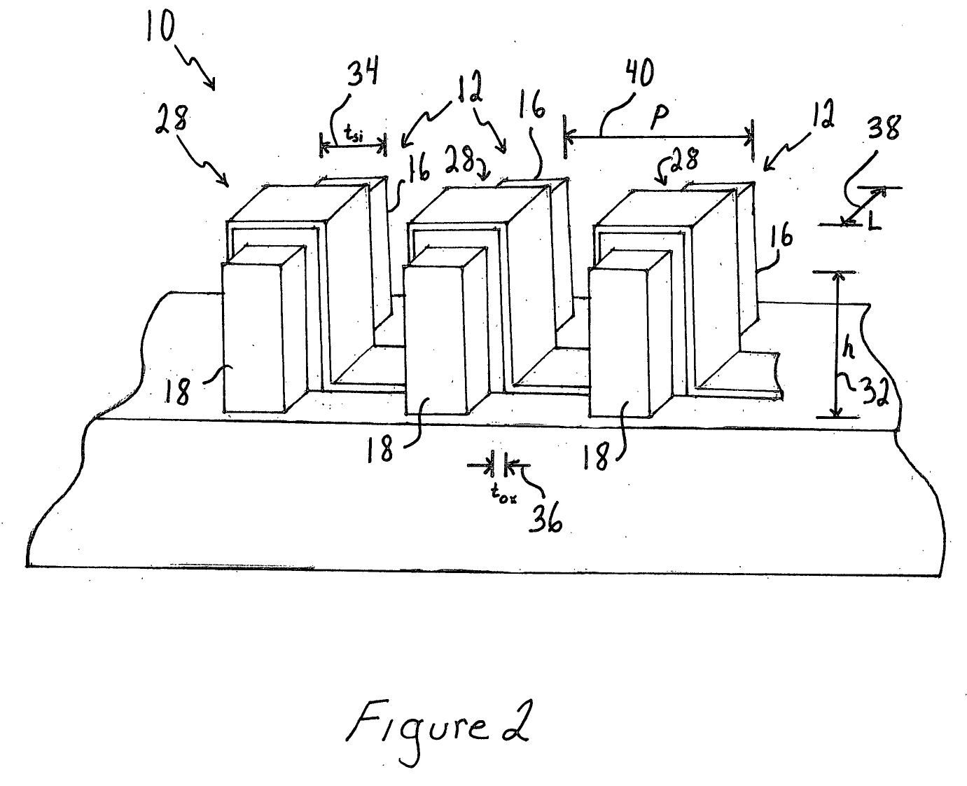

Referring now to FIGS. 1a and 1b, a Fin-Field-Effect-Transistor (FinFET) semiconductor device 10 includes a source region 16, a drain region 18, and a channel region 17 (see FIG. 1b) defined between the source region 16 and the drain region 18. The source region 16, drain region 18, and channel region 17 form a fin structure 12. The fin structure 12 is fabricated on a substrate 14 and extends upwardly away from the substrate 14. The fin structure may be fabricated using any conventional fabrication method such as, for example, deposition or epitaxial growth. The fin structure 12 has an approximate rectangular cross-section. Illustratively, the fin structure 12 and the substrate 14 are formed from silicon. The substrate 14 may be a portion of a semiconductor wafer. The wafer may be any type of semiconductor wafer. In one particular embodiment, the wafer is a Silicon On Insulator (SOI) wafer having a silicon layer formed over an insulating layer such as silicon dioxide. Although the FinFET device 10 illustrated in FIG. 1 includes a single fin structure 12, in other embodiments, the FinFET device 10 may include any number of fin structures 12 as discussed below in regard to FIG. 2.

The source region 16 and the drain region 18 may be established by one of a number of doping methods including, for example, ion implantation or chemical vapor deposition. The source region 16 and drain region 18 may be doped as P-type or N-type regions. The channel region 17 may also be doped, lightly doped, or left in an intrinsic state. Accordingly, the FinFET device 10 may be formed as a P-channel or N-channel device.

The fin structure 12 also include a gate region 20 formed on a first side 22 and a gate region 24 formed on a second side 26 over the channel region 17. However, in some embodiments, the fin structure 12 may include only one gate region formed on one side of the fin structure. Each of the gate regions 20, 24 include an insulating layer 21 formed over the channel region 17 and extending over a portion of the source region 16 and drain region 18. In addition, each gate region 20, 24 includes a gate conductive layer 23 formed over the insulting layer 21. The gate conductive layer 23 may be made of any suitable conductive material such as polysilicon, copper alloy, or the like. The oxide insulting layer 21 may be made of any suitable insulating material such as silicon oxide. Because the gates 20, 24 are formed on opposite sides 22, 26, the gates 20, 24 form a symmetrical double gate. Illustratively, the gates 20, 24 are coupled together to form a double gate region 28 that wraps around a top side 30 of the fin structure 12. However, in other embodiments, the gates 20, 24 may not be tied together or the FinFET device 10 may include only a single gate.

The FinFET device 10 is fabricated according to a set of parameters. For example, the fin structure 12 is fabricated to extend upwardly away from the substrate 14 to a fin height 32. In addition, the fin structure 12 is fabricated to have a predetermined horizontal thickness 34 (i.e., body thickness, tₛᵢ). Similarly, the insulating layer 21 of the gate regions 22, 24, 28 is fabricated to have a predetermined thickness 36 (i.e., gate oxide thickness, tₒₓ) and a predetermined length 38 (i.e., gate length, L). Typical FinFET devices are fabricated according to standard or guideline parameters for each technology node. A technology node is typically designated by a number followed by a metric (e.g., 90 nm technology node, 65 nm technology node, etc.). A technology node defines a minimum geometry spacing, width, radius, or the like that defines the technology. For example, the technology node may define a minimum distance between metal interconnects, a minimum contact dimensions, a minimum space defined between diffusion areas, or the like. Regardless, in any such technology node process which includes a FinFET semiconductor device, the fin structures will have a minimum fin structure height accordingly to the particular technology node. For example, the International Technology Roadmap for Semiconductors (ITRS) has established a guideline for minimum fin height for the 65 nm technology node of about 32.5 nanometers. Additionally, the ITRS has established other guidelines for other design parameters for the 65 nm technology node including a minimum supply voltage of about 0.77 volts, a physical gate length, L, of about 25 nm, a physical oxide thickness, tₒₓ, of about 1.0 nm, a body thickness, tₛᵢ, of about 11 nm, and a minimum fin pitch, p, of about 65 nm. The Fin pitch is defined as the distance between two fin structures measured from, for example, a middle point of each fin structure. In embodiments, wherein the FinFET device 10 has a single fin, the fin pitch may be defined as the minimum distance between the fin structure of a first FinFET device 10 and a fin structure of a second FinFET device 10.

Because FinFET channel width is perpendicular to the semiconductor plane, the effective channel width per unit planar area (i.e., the footprint of the semiconductor device) may be increased by increasing the height of the fin structure. It should be noted that while increasing the height of the fin structure increases the effective channel, the foot print (i.e. planar area) of the device remains substantially constant. Increasing the channel width of a FinFET device allows an increase in the drive current of the device.

The FinFET device 10 is fabricated according to parameters differing from the standardized parameters for a given technology node. In particular, the height 32 of FinFET device 10 is fabricated to be greater than the minimum fin height for the given technology node. In one particular embodiment, the FinFET device 10 includes a fin structure having a height that is about fifty percent greater than the minimum fin structure height. In a more particular embodiment, the FinFET device 10 includes a fin structure having a height that is about sixty-nine percent greater than the minimum fin structure height. For example, in the 65 nm technology node which sets a minimum fin structure height of 32.5 nm, the FinFET device 10 may include a fin structure 12 having a height of about 55 nm. The fin structure 12 may be increased in height above the minimum fin structure height to a maximum fin structure height. To achieve planar area efficiency, the minimum fin structure height is generally defined as the minimum fin pitch divided by two. The maximum fin structure height, hₘₐₓ, is based on a maximum fin aspect ratio for any particular technology node. The maximum fin aspect ratio, aₘₐₓ, is defined as the maximum fin height, hₘₐₓ, divided by the body thickness, tₛᵢ, of the fin structure, or aₘₐₓ=hₘₐₓ/tₛᵢ. Accordingly, as the height of the fin structure is increased, the body thickness of the fin structure must be increased to keep a constant fin aspect ratio. Because the body thickness is generally kept constant, and in some embodiments may be equal to the minimum body thickness, the maximum height of the fin structure 12 may be approximately equal to the maximum fin aspect ratio, aₘₐₓ, times the body thickness, tₛᵢ, of the fin structure 12. The maximum fin aspect ratio value aₘₐₓ, may be provided by a standardized technology node process, by the specific design, circuitry, or application, or as a industry standard. Generally, the semiconductor industry uses a maximum fin aspect ratio of about 5.0. However, in some embodiments, the FinFET device 10 may have fin structures 12 having maximum fin aspect ratios above 5.0. For example, fin aspect ratios of 5.0 to 10.0 may be used. Accordingly, the fin height 32 of the fin structure 12 may be designed to be any value greater than the minimum fin height and less than (or equal to) the maximum fin aspect ratio times the body thickness of the fin structure 12. In one particular embodiment, the FinFET device 10 includes a fin structure 12 having a height equal to the maximum fin aspect ratio value times the body thickness of the fin structure.

In a typical FinFET device, current flow is approximately parallel to the wafer plane and channel width is approximately perpendicular to the wafer plane. As illustrated in FIG. 1a, current flow in the FinFET semiconductor device 10 is generally in the direction of arrow 100. The channel width of FinFET device 10 is measured generally in the direction of arrow 102. The effective channel width of a two-channel single-fin FinFET device is approximately equal to two times the height of the fin structure. A greater channel width can be achieved by including multiple fin structures.

Referring now to FIG. 2, in some embodiments, the FinFET semiconductor device 10 may include multiple fin structures 12. Each fin structure 12 includes a source region 16 and a drain region 18. Each fin structure 12 includes a gate region 28 fabricated to wrap over (i.e., both vertical sides 22, 24 and top side 30 of the fin structure 12) the fin structure 12. Each of the gate regions 28 are coupled together. The effective channel width of a FinFET device having multiple fins is approximately equal to two (assuming dual gate) times the number of fin structures times the height of the fin structures. Accordingly, the FinFET device 10 illustrated in FIG. 2 has an effective channel width equal to about six times the fin height 32 of the fin structures 12. The fin structures 12 are separated by a pitch distance 40 approximately equal to the minimum fin pitch value. The fin structure 12 of the FinFET device 10 illustrated in FIG. 2 may have a fin height 32 determined in the same manner as the fin structure 12 of the FinFET device 10 illustrated in FIGS. 1a and 1b. That is, the fin height 32 of the fin structures 12 of the multi-fin FinFET device 10 may be designed to be any value greater than the minimum fin height and less than (or equal to) the maximum fin aspect ratio times the body thickness of the fin structures 12. In one particular embodiment, the FinFET device 10 of FIG. 2 includes multiple fin structures 12 having fin heights 32 equal to the maximum fin aspect ratio value, aₘₐₓ, times the body thickness, tₛᵢ, of the fin structure. Typically, each fin of the multi-fin FinFET device 10 has the same fin height 32 and body thickness 34.

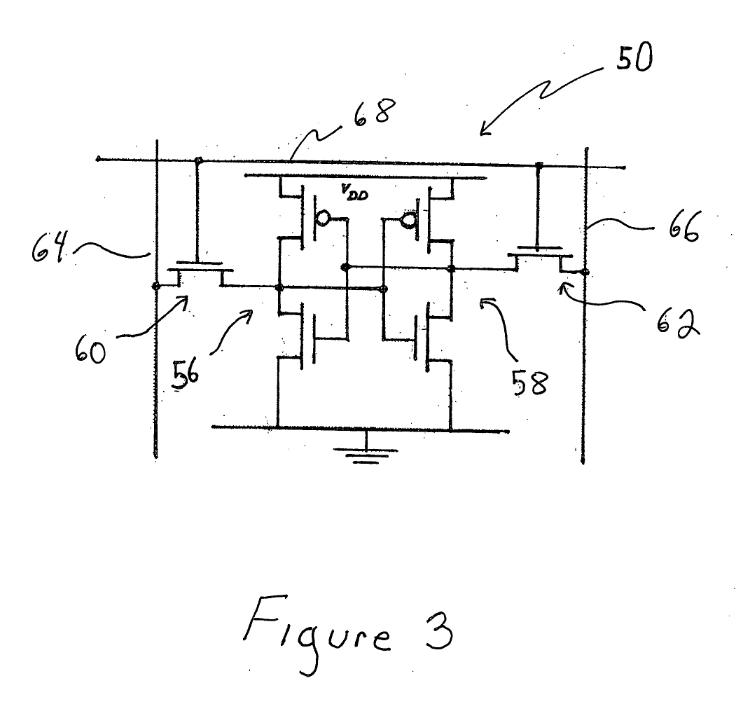

The FinFET device 10 may be incorporated into any of a number of semiconductor devices. Referring to FIG. 3, an example of a semiconductor device including a FinFET device 10 is a memory device. The memory device may include any number of memory cells 50. The memory device illustrated in FIG. 3 may be a static random access memory (SRAM) device or may alternatively be or include other types of memory devices. Additionally, although the memory cell 50 is illustrated as a six-FinFET memory cell, the memory cell 50 may alternatively include more or less FinFET devices 10.

The memory cell 50 includes two cross-coupled inverters 56, 58 and two access transistors 60, 62. The inverters 56, 58 include two transistors each, one N-channel and one P-channel. Each transistor of the inverter 56, 58 and the access transistors 60, 62 are embodied as FinFET devices 10. The inverters 56, 58 are coupled on a supply side to a power supply voltage, Vdd, and on a reference side to ground reference. The inverters 56, 58 are also each coupled to the drain terminals of the access transistors 60, 62. The source terminal of the access transistor 60 is coupled to a BIT line 64 and the source terminal of the access transistor 62 is coupled to a notBIT line 66. The gate terminals of the access transistors 60, 62 are coupled to a WORD line 68.

In operation, bit data is stored in the inverters 56, 58 of the memory cell 52. The bit data may be accessed or overwritten via the access transistors 60, 62. To do so, the WORD line 68 is used to bias, or turn on, the access transistors 60, 62. Data can then be written to the BIT line 64 and notBIT line 66 to store the bit data in the inverters 56, 58. Alternatively, bit data previously stored in the inverters 56, 58 may be read using the lines 64, 66.

In typical memory devices, the supply voltage, Vdd, is equal to the minimum supply voltage for the given technology node. For example, for a 65 nm technology node, the International Technology Roadmap for Semiconductors (ITRS) has established a guideline for minimum supply voltage of 0.77 volts. However, the FinFET devices 10 of the memory device 50 have a greater channel width because of a greater than minimum fin height. Because the FinFET devices 10 have a greater channel width, the drive current in the devices 10 is also increased allowing for a lower supply voltage than the minimum supply voltage. Accordingly, the memory device may have a supply voltage, Vdd, that is lower than the minimum supply voltage specified for the particular technology node. In one particular embodiment, the memory device has a supply voltage that is more than ten percent less than the minimum supply voltage. In another particular embodiment, the memory device 50 has a supply voltage that is about eighteen percent less than the minimum supply voltage.

In addition to a lower supply voltage, Vdd, the FinFET devices 10 of the memory device 50 may be designed to have a voltage threshold that is greater than the minimum voltage threshold for any particular technology node. To do so, the gate workfunction of the FinFET devices 10 may be adjusted by altering the metallic and/or alloy materials forming the gates and/or by altering the body doping of the channel region 17. Regardless, it should be appreciated that the voltage threshold of any FinFET device 10 may be designed to be greater than the minimum voltage threshold by adjusting the gate workfunction. In one particular embodiment, the FinFET device 10 has a threshold voltage that is more than ten percent greater than the minimum voltage threshold. In another particular embodiment, the FinFET device 10 has a voltage threshold that is thirty-five percent greater than the minimum voltage threshold.

It should be appreciated that the FinFET device 10 may have improved performance compared to contemporary FinFET devices. For example, the FinFET device 10 may have a lower sub-threshold leakage, a lower gate leakage, a lower dynamic energy, a higher static noise margin, and a higher critical charge for soft error immunity. However, such increased performance is not a requirement of the FinFET device 10 and such advantages should not be construed as limitations to the FinFET device 10.

While the disclosure has been illustrated and described in detail in the drawings and foregoing description, such an illustration and description is to be considered as exemplary and not restrictive in character, it being understood that only illustrative embodiments have been shown and described and that all changes and modifications that come within the spirit of the disclosure are desired to be protected.

There are a plurality of advantages of the present disclosure arising from the various features of the device described herein. It will be noted that alternative embodiments of the device of the present disclosure may not include all of the features described yet still benefit from at least some of the advantages of such features. Those of ordinary skill in the art may readily devise their own implementations of the device that incorporate one or more of the features of the present invention and fall within the spirit and scope of the present disclosure as defined by the appended claims.

1. A FinFET semiconductor device fabricated on a substrate according to a predetermined technology node process that defines a minimum fin height, the FinFET semiconductor device comprising:
a source region,
a drain region, and
a channel region defined between the source and drain regions, the source, drain and channel regions forming a fin structure extending upwardly away from the substrate to a fin height greater than the minimum fin height.

2. The FinFET semiconductor device of claim 1, wherein the fin height is more than about fifty percent greater than the minimum fin height.

3. The FinFET semiconductor device of claim 2, wherein the fin height is about sixty-nine percent greater than the minimum fin height

4. The FinFET semiconductor device of claim 1, wherein the predetermined technology node process further defines a minimum fin pitch value, p, and a maximum fin aspect ratio value, aₘₐₓ,
and wherein the fin structure has a fin body thickness, tₛᵢ, the fin height, h, being determined according to the following equation:
p/2<h=<aₘₐₓ*tₛᵢ.

5. The FinFET semiconductor device of claim 4, wherein the fin height, h, is approximately equal to aₘₐₓ*tₛᵢ.

6. The FinFET semiconductor device of claim 4, wherein the minimum fin pitch value, p, is equal to about 65 nanometers.

7. The FinFET semiconductor device of claim 1, wherein the fin height is approximately equal to a product of a standard maximum fin aspect ratio value and a body thickness of the fin structure.

8. The FinFET semiconductor device of claim 1, wherein the technology node process is the 65 nanometer technology node process.

9. The FinFET semiconductor device of claim 1, further comprising a first gate region adjacent to the channel region on one side of the fin structure and a second gate region adjacent to the channel region on an opposite side of the fin structure.

10. The FinFET semiconductor device of claim 9, wherein the channel region and the gate region define a threshold voltage of the FinFET semiconductor device, and the technology node process further defines a minimum voltage threshold,
and wherein the threshold voltage of the FinFET semiconductor device is greater than the minimum voltage threshold.

11. The FinFET semiconductor device of claim 1, wherein the FinFET semiconductor device forms a portion of an memory cell.

12. An electrical circuit comprising:
a FinFET semiconductor device fabricated on a substrate according to a predetermined technology node process that defines a minimum fin height and a minimum supply voltage, the FinFET semiconductor device having a source region, a drain region and a channel region defined therebetween, the source, drain and channel regions forming a fin structure extending upwardly away from the substrate to a fin height greater than the minimum fin height, the fin height allowing for a supply voltage applied to the FinFET semiconductor device that is less than the minimum supply voltage.

13. The electrical circuit of claim 12, wherein the supply voltage is more than about ten percent lower than the minimum supply voltage.

14. The electrical circuit of claim 13, wherein the supply voltage is about eighteen percent lower than the minimum supply voltage.

15. The electrical circuit of claim 12, wherein the predetermined technology node process further defines a minimum gate workfunction, the minimum gate workfunction defining a minimum voltage threshold, and wherein the FinFET semiconductor device has a voltage threshold greater than the minimum voltage threshold.

16. The electrical circuit of claim 12, wherein the fin height is more than about fifty percent greater than the minimum fin height.

17. The electrical circuit of claim 16, wherein the fin height is about sixty-nine percent greater than the minimum fin height

18. The electrical circuit of claim 12, wherein the predetermined technology node process further defines a minimum fin pitch value, p, and a maximum fin aspect ratio value, aₘₐₓ,
and wherein the fin structure has a fin body thickness, tₛᵢ, the fin height, h, being determined according to the following equation:
p/2<h=<aₘₐₓ*tₛᵢ.

19. The electrical circuit of claim 18, wherein the fin height, h, is approximately equal to aₘₐₓ*tₛᵢ.

20. The electrical circuit of claim 12, wherein the fin height is approximately equal to a product of a standard maximum fin aspect ratio value and a body thickness of the fin structure.

21. The electrical circuit of claim 12, wherein the FinFET semiconductor device forms a portion of a memory cell.

22. A method of fabricating a FinFET semiconductor device on a substrate according to a predetermined technology node fabrication process that defines a minimum fin height, the method comprising:
forming on the substrate a fin structure having a source region, a drain region and a channel region therebetween, the fin structure extending upwardly away from the substrate to a fin height greater than the minimum fin height,
forming a gate region adjacent to the channel region on at least one side of the fin structure.

23. The method of claim 22, wherein the predetermined technology node process further defines a minimum fin pitch value, p, and a maximum fin aspect ratio value, aₘₐₓ, and wherein the fin structure has a fin body thickness, tₛᵢ,
and wherein forming the fin structure includes forming the fin structure with the fin height, h, being determined according to the following equation:
p/2<h=<aₘₐₓ*tₛᵢ.

24. The method of claim 23, wherein forming the fin structure includes forming the fin structure with the fin height, h, approximately equal to aₘₐₓ*tₛᵢ.

25. The method of claim 22 wherein forming a gate region includes forming a first gate region adjacent to the channel region on one side of the fin structure and forming a second gate region adjacent to the channel on an opposite side of the fin structure.

26. The method of claim 25 further including forming a single electrically conductive gate over the first and second gate regions.

27. The method of claim 22 further including forming an electrically conductive gate over the channel region on the at least one side of the fin structure.

28. An SRAM device fabricated on a substrate according to a predetermined technology node process that defines a minimum fin height, the SRAM device comprising at least one FinFET device having a source region, a drain region defining a channel region therebetween the source, drain and channel regions together forming a fin structure extending upwardly away from the substrate to a fin height that is greater than the minimum fin height.
